(19) United States
(12) Patent Application Publication
(10) Pub. No.: US 2013/0025643 A1
(43) Pub. Date: Jan. 31, 2013

(54) SOLAR CELL DEVICE COMPRISING AN AMORPHOUS DIAMOND LIKE CARBON SEMICONDUCTOR AND A CONVENTIONAL SEMICONDUCTOR

(71) Applicant: BURNING SOLAR LTD., Holon (IL)

(72) Inventor: Moshe Mahrize, Holon (IL)

(73) Assignee: BURNING SOLAR LTD., HOLON (IL)

(21) Appl. No.: 13/647,800

(22) Filed: Oct. 9, 2012

Related U.S. Application Data
(63) Continuation-in-part of application No. 12/525,918, filed on Aug. 24, 2009, now Pat. No. 8,309,842.
(60) Provisional application No. 60/901,033, filed on Feb. 13, 2007.

(51) Int. Cl. H01L 31/105; H01L 31/042; H01L 31/18; H01L 35/02

(52) U.S. Cl. 136/206; 136/255; 136/244; 438/54; 257/E31.061

(57) ABSTRACT

A device and method of manufacture of a:DLC multi-layer doping growth comprising the steps of: forming at least an a:DLC layer in one process over a conventional semiconductor layer, thereby creating a plurality of successively connected PIN/PN junctions, each PIN/PN junction being a photo diode, starting from a first junction and ending in a last junction, respective PIN/PN junctions having p-type, n-type, and intrinsic layers; varying the sp³/sp² ratio of at least the respective p-type and n-type layers and doping with at least silver to enhance electron mobility in respective PIN junctions; and connecting the plurality of a:DLC layers between electrodes at the first side and the second side to create a device having optimized spectral response to being oriented to a light source. A device comprises at least any kind of PIN/PN junction and an a:DLC PIN/PN junction, and can be connected as an array of devices.

### RELATED APPLICATIONS

This application is a continuation-in-part of U.S. patent application Ser. No. 12/525,918 that claims priority from PCT application No. PCT/IL08/00189 filed Feb. 13, 2008, and which further claims priority from U.S. Provisional Patent Application No. 60/901,033 filed Feb. 13, 2007, which are incorporated herein by reference.

### FIELD OF THE INVENTION

The present invention relates to a method and device of amorphous diamond like carbon thin multi-layer doping growth, and in particular, it concerns a process of forming a variable structure with mix control (sp³/sp² ratio) to obtain a large spectrum energy gap for multifunction photovoltaic and thermal solar cells and other applications.

### BACKGROUND OF THE INVENTION

In recent years, amorphous Diamond Like Carbon (a:DLC, or a-C:H) films have been developed. a:DLC films are easier to deposit on large substrate areas (such as plastic), at low temperature, as compared to CVD diamond-like carbon (DLC) films. The unique properties of a:DLC films are similar to those of single crystal bulk diamonds, including: high hardness, low friction coefficient, chemical inertness, infrared transparency, high electrical resistivity, and smoothness; make them suitable to many applications.

As conventional energy sources may be depleted in the future, meeting the increasing world energy demand will certainly involve increased use of solar energy. Therefore, solar cell research has been accelerated in recent years. Although silicon and compound-semiconductor-based solar cells have dominated the market for the last few decades, low-cost, stable and highly efficient solar cells are yet to be commercially realized due to high material and production costs. However, with the emergence of carbon semiconductor materials, the situation is expected to change. Carbon is readily available in nature. Carbon exhibits outstanding properties such as: chemical inertness; high hardness; high thermal conductivity; high dielectric strength, and infrared (IR) optical transparency. Carbon atoms in a:DLC films may have three different atomic coordinates: The sp³ (tetrahedral or aliphatic), or “sp³” herein below and in the claims which follow, is the typical type of bond for diamond, sp² (trigonal or aromatic) or “sp²” herein below and in the claims which follow, typical for graphite, and sp¹ (linear or acetylenic) or “sp¹” herein below, typical for amorphous carbon.

The interesting and unique feature of carbon is that properties such as those noted above can be tuned over an unusual wide range from that of conductor graphite (˜0.0 eV) to that of insulating diamond (˜5.5 eV) by varying the ratio of sp³ and sp² hybridized bonds. Hence carbon has attracted the attention of the researchers for its application in solar or photovoltaic (PV) cells. Carbon-based heterostructures such as metal insulator semiconductor (MIS) diodes, Schottky diodes, metal insulator semiconductor field effect transistor, heterojunction diodes, and photovoltaic cells on silicon have already been reported; thereby indicating the potential of carbon materials in electro-optic devices. However, relatively few publications are available on the PV properties of C/Si hetero-structures. It is worth noting that virtually all the researchers working with carbonaceous photovoltaic cells reported the overall photoresponse of their cells. But the separation of respective contributions of carbon and silicon in a C/Si PV cell is yet to be realized. At present, there is a need to advance work on the spectral photoresponse characteristics of C/Si heterostructures and to visualize the contribution of C and Si separately to understand the nature and improve the characteristics for the practical implementation of a:DLC-based PV cells.

Previous studies, such as Aisenberg, S., Kimock, F. M., Mater. Sci. Forum, 52-53, (1988), 1, incorporated herein by reference, show that the energy of the carbon species generated by various preparation methods is different and plays an important role in controlling the sp³/sp² ratio. Also It is recognized that the population concentrations of sp³ and sp² bonds are also dependent on different kinds of precursor materials, which dictate the sp³/sp² ratio of a:DLC structures films. Hence the properties of thin carbon films depend on the method of deposition, deposition parameters and precursor materials used.

There are a number of prior art dealing with the use of amorphous carbon and/or diamond-like carbon layered structures and their fabrication, among them: U.S. Pat. No. 6,078,133 (Menu et al.); U.S. Pat. No. 7,214,600 (Won et al.); U.S. Pat. No. 5,206,534 (Birkle et al.); and U.S. Pat. No. 5,366,556 (Prince et al.), incorporated herein by reference. In addition US Patent publications US2007/0042667 and US2006/0078677, herein incorporated by reference, also deal with diamond-like carbon structures and devices. While these prior art touch on many aspects concerning overall fabrication and some precursor details, detailed control of the sp3 and sp2 bonding levels (and, as a result, the sp3/sp2 ratio) is not disclosed.

An additional parameter making carbon films suitable candidates for PV cells is activation energy. Studies, such as J. Robertson, Adv. Phys., 35 (1986), 317 and C. Benndorf, M Grischke, A. Brauer and F. Thieme, Surf. Coat. Technol., 36 (1988), 171, both incorporated herein by reference, for a:DLC films (such as those used in PV cells) show that a deposited doped a:DLC film increases activation energy as compared with undoped film. Study of activation energy reveals that the Fermi level of the carbon film moves from the valence band edge to near the conduction band edge through the mid-gap. The Tauc gap, and conductivity are also influenced with film doping.

Ingram et al. in U.S. Pat. No. 5,562,781, herein incorporated by reference, describes a PV cell comprising a plurality film layers, at least one of the layers being a semiconductor film of amorphous hydrogenated carbon. PIN junctions are formed of films; all made of amorphous, hydrogenated carbon and vary only by dopant levels without each PIN junction. There are variations in band gap from one PIN junction to the next in order that the photovoltaic effect in each PIN junction will be caused by a different portion of the spectrum of light. Ingram describes an arc-discharge deposition technique, which apparently spans various stages in fabrication and he refers to conventional doping to control material properties.

There is therefore a need to for better and/or novel control of the sp³/sp² ratio and utilizing doping in a:DLC films to fabricate improved photovoltaic cells. It would be even further advantageous if certain integration between standard photovoltaic cells and a:DLC based photovoltaic cells be made possible.

Further purposes and advantages of this invention will appear as the description proceeds.

### SUMMARY OF THE INVENTION

In a first aspect the invention is an apparatus for conversion of solar energy into electrical energy. The apparatus comprises: a first electrode, a PIN junction photo diode formed over the first electrode, at least an a:DLC PIN junction formed over the tunnel diode serially connected to the tunnel diode, and a second electrode formed over the at least an a:DLC PIN junction. The band gap of the at least an a:DLC PIN junction must be different from the band gap of the PIN junction.

Embodiments of the apparatus of the first aspect of the invention can further comprise a tunnel diode formed over the PIN junction for serial connection with the silicon PIN junction for directing current through the apparatus.

In embodiments of the apparatus of the first aspect of the invention the PIN junction can be made of one of: crystalline silicon, amorphous silicon, germanium, gallium-arsenide, copper indium gallium selenide (CIGS), dye solar, organic semiconductor.

In embodiments of the apparatus of the first aspect of the invention the at least an a:DLC PIN junction can be comprised of a first a:DLC PIN junction and a second a:DLC PIN diode connected in series. In an embodiment the first a:DLC PIN junction and the second a:DLC PIN junction each have different band gaps which are both different from the ban gap of the silicon PIN junction. In an embodiment the band gap of an a:DLC PIN junction closer to the first electrode has a wider band gap than a subsequent a:DLC PIN junction closer to the second electrode.

Embodiments of the apparatus of the first aspect of the invention can further comprise at least a Fresnel lens that collects incident light.

Embodiments of the apparatus of the first aspect of the invention can further comprise a structure to collect thermal energy for conversion to electrical energy.

The apparatus of the first aspect of the invention can be arranged as an array of cells for conversion of solar energy into electrical energy, wherein each cell of the array of cells is an apparatus of the first aspect of the invention.

In a second aspect the invention is a method of manufacture of a structure for conversion of solar energy into electrical energy. The method comprises the steps of forming a first electrode of conductive material; forming a PIN junction photo diode over the first electrode having a first band gap; forming at least an a:DLC PIN junction over the tunnel diode that is serially connected to the tunnel diode, wherein each of the at least an a:DLC PIN junction having a predetermined band gap; and forming a second electrode formed over the at least an a:DLC PIN junction. According to this method, the band gap of the PIN junction and each of the predetermined band gaps must be different from each other.

Embodiments of the method of the second aspect of the invention can further comprise forming a current directing tunnel diode over the PIN junction such that a serial connection is created between the PIN junction and the tunnel diode.

In embodiments of the method of the second aspect of the invention the PIN junction can be made of one of: crystalline silicon, amorphous silicon, germanium, gallium-arsenide, copper indium gallium selenide (CIGS), dye solar, organic semiconductor.

Embodiments of the second aspect of the method of the invention can further comprise forming at least a Fresnel lens for collection of incident light.

Embodiments of the second aspect of the method of the invention can further comprise forming a structure that collects thermal energy for conversion to electrical energy.

In a third aspect the invention is a method of manufacture of an array of structures for conversion of solar energy into electrical energy, the method comprises the steps of: forming a first electrode of conductive material; forming a plurality of PIN junction photo diode over the first electrode having a first band gap; forming a plurality of at least an a:DLC PIN junction over the respective plurality of tunnel diodes each of the at least an a:DLC PIN junction being serially connected to s respective tunnel diode, wherein each of the at least an a:DLC PIN junction having a predetermined band gap; and forming a second electrode formed over the plurality of at least an a:DLC PIN junction. According to this method the band gap of the plurality of PIN junctions and each of the predetermined band gap must be different from each other.

Embodiments of the method of the third aspect of the invention can further comprise forming a plurality of tunnel diodes over the respective plurality of PIN junction such that a serial connection is created between respective PIN junction and tunnel diodes.

In embodiments of the method of the third aspect of the invention the PIN junction can be made of one of: crystalline silicon, amorphous silicon, germanium, gallium-arsenide, copper indium gallium selenide (GIGS), dye solar, organic semiconductor.

Embodiments of the method of the third aspect of the invention can further comprise forming at least a Fresnel lens for collection of incident light.

Embodiments of the method of the third aspect of the invention can further comprise forming a structure that collects thermal energy for conversion to electrical energy.

In a fourth aspect the invention is a diode comprising a first layer made of semiconductor layer having a first polarity and a second layer made of an a:DLC layer having a second polarity, the second polarity being opposite to the first polarity the layers arranged such that a PN junction is formed between the first layer and the second layer.

In embodiments of the diode of the invention the first polarity is one of: p-type, n-type.

Embodiments of the diode of the invention can further comprise an intrinsic layer between the first layer and the second layer.

In embodiments of the diode of the invention the intrinsic layer is made from an a:DLC material.

In embodiments of the diode of the invention the semiconductor can be one of: crystalline silicon, amorphous silicon, germanium, gallium-arsenide, copper indium gallium selenide (CIGS), dye solar, organic semiconductor.

In a fifth aspect the invention is an apparatus for conversion of solar energy into electrical energy. This apparatus comprises at least an a:DLC PIN junction having a first band gap and at least another device for conversion of solar energy into electrical energy having a second band gap that is different from the first band gap. According to this method each of the at least an a:DLC PIN junction and the at least another device providing current from the apparatus in one of: parallel to each other; in series of each other.

In embodiments of the apparatus of the fifth aspect the invention the at least another device can be one of: a crystalline silicon PIN junction photo diode, an amorphous silicon PIN junction photo diode, a gallium-arsenide PIN junction photo diode, a crystalline PIN junction photo diode, a copper indium gallium selenide (CICS) PIN junction photo diode, a dye solar PIN junction photo diode, an organic semiconductor PIN junction photo diode, an a:DLC PIN junction.

Embodiments of the apparatus of the fifth aspect the invention can further comprise at least a Fresnel lens that collects incident light.

Embodiments of the apparatus of the fifth aspect the invention can further comprise a structure to collect thermal energy for conversion to electrical energy.

All the above and other characteristics and advantages of the invention will be further understood through the following illustrative and non-limitative description of embodiments thereof, with reference to the appended drawings.

### BRIEF DESCRIPTION OF THE DRAWINGS

FIG. 1 is a schematic diagram of a device with a plurality of films in accordance with an embodiment of the current invention;

FIG. 2A is a schematic diagram of an enhanced device with a double sided structure of a device similar to the device of FIG. 1 with concentration lenses;

FIG. 2B is a schematic diagram of an enhanced device with one side similar to the device of FIG. 1 and the other side of a device for thermal conversion to electrical energy;

FIG. 3A is a three dimensional of an apparatus having a first structure using semiconductor PIN junction array of a first band gap and a second structure using a:DLC PIN junction array having at least a second band gap different from the first band gap;

FIG. 3B is a schematic diagram of an enhanced device and is a schematic cross section of the apparatus shown in FIG. 3A where the first and second structures and are connected to respective loads;

FIG. 4 is a schematic diagram of an enhanced device and is an electrical schematic of the connection of any kind of PIN junction to an a:DLC PIN junction by a current directing tunnel diode according to a principle of the invention;

FIG. 5 is a schematic diagram of an enhanced device and is a schematic diagram of the layers comprising a PIN junction according to a principle of the invention; and

FIG. 6 is a schematic diagram of an enhanced device 600 and is a schematic diagram of the layers comprising a PV junction where one of the doped layers is an a:DLC (p or n type) layer and the other layer is an opposite polarity of any kinds PV semiconductor layer.

### DETAILED DESCRIPTION OF EMBODIMENTS OF THE INVENTION

A device and method of manufacture of a:DLC multi-layer doping growth comprising the steps of: forming at least an a:DLC layer in one process over a conventional semiconductor layer, thereby creating a plurality of successively connected PIN/PN junctions, each PIN/PN junction being a photo diode, starting from a first junction and ending in a last junction, respective PIN/PN junctions having p-type, n-type, and intrinsic layers; varying the sp³/sp² ratio of at least the respective p-type and n-type layers and doping with at least silver to enhance electron mobility in respective PIN junctions; and connecting the plurality of a:DLC layers between electrodes at the first side and the second side to create a device having optimized spectral response to being oriented to a light source. A device comprises at least any kind of PIN/PN junction and an a:DLC PIN/PN junction, and can be connected as an array of devices.

The present invention is a method and device of amorphous diamond like carbon multi-layer doping growth, and in particular, it concerns a process of forming a variable structure with mix control (sp³/sp² ratio) to obtain a large spectrum energy gap for multi-junction photovoltaic cells and other applications. The principles method for amorphous diamond like carbon multi-layer doping growth according to the present invention may be better understood with reference to the drawings and the accompanying description.

In the specification and the claims herein below, the following terms are defined.

“Amorphous Diamond-like carbon” (alternatively “a:DLC” and/or “a-C:H”) is intended to mean a hydrogenated carbonaceous material having carbon atoms as the majority element, with a substantial amount of such carbon atoms bonded in distorted tetrahedral coordination. a:DLC can typically be formed by PVD processes, although CVD or other processes could be used such as vapor deposition processes. Notably, a variety of other elements can be included in the DLC material as either impurities, or as dopants, including without limitation, hydrogen, sulfur, phosphorous, boron, nitrogen, silicon, and tungsten, among others.

“sp³/sp² ratio” is intended to mean the ratio between complete diamond structure versus complete graphite structure of the a:DLC material, with the terms “spa” and “sp²” defined hereinabove.

“One process” is intended to mean a process that takes place substantially concomitantly in one processing tool—as opposed to a process that entails multiple processing tools and/or iterative steps involving one or more processing tools over a non-concomitant time period. In most cases, one process offers advantages in time and cost, among other advantages, as compared to similar procedures involving many processes.

“Work function” is intended to mean the amount of energy, typically expressed in eV, required to cause electrons in the highest energy state of a material to emit from the material into a vacuum space. Thus, a material such as copper having a work function of about 4.5 eV would require 4.5 eV of energy in order for electrons to be released from the surface into a theoretically perfect vacuum at 0 eV.

“Thermoelectric conversion” relates to the conversion of thermal energy to electrical energy or of electrical energy to thermal energy, or flow of thermal energy. Further, in the context of embodiments of the present invention, an a:DLC employed in a photovoltaic cell typically operates under thermionic emission. As discussed herein below, thermionic emission is a property wherein increased electron emission is achieved from a material with increases in temperatures. Materials such as a:DLC exhibit thermionic emission at temperatures far below that of most others materials. For example, while many materials tend to exhibit substantial thermionic emission or temperature related effects in emission properties at temperatures over about 1,100 degrees C., a:DLC exhibits increases in emission at temperature changes near room temperature up to 1000 degrees C. or more. A thermionic material such as a:DLC can be useful at temperatures from below room temperature to about 300 degrees C.

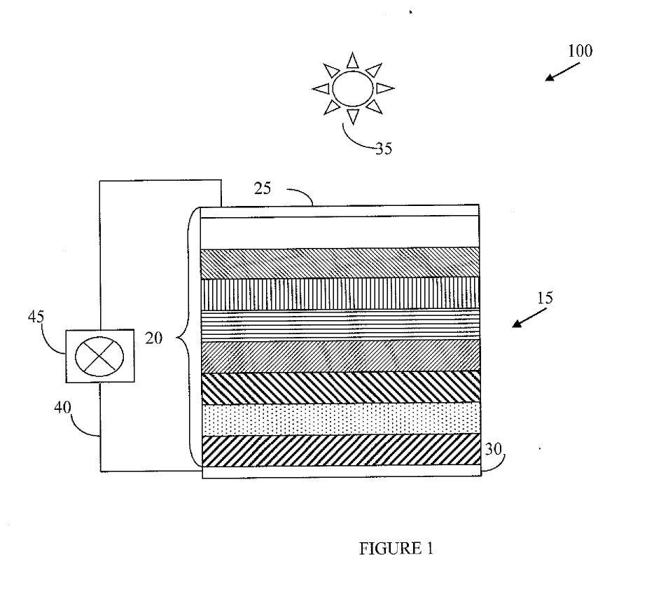

Reference is presently made to FIG. 1, which is a schematic diagram of a device 10, such as a PV cell or solar cell, having a plurality of films 15, in accordance with an embodiment of the present invention. The plurality of films comprises a number of PIN junctions 20, each PIN junction being a photo diode, formed by three respective a:DLC thin films (trios)—not shown in the FIG. 1.—per PIN junction, but explained in more detail in FIG. 5; the layers deposited successively upon one another. In an embodiment of the current invention, the PIN trio closest to electrode layer 25 (graphene) or any kind conductive transparent oxide (CTO) electrode, such as but not limited to, polymer, etc., as described further herein below. In contrast, the PIN trio closest to electrode layer 30 an elastic foil, such as but not limited to, Cu, stainless steel foil or an elastic foil, is fabricated from an a:DLC layer with a high sp² bonding (graphite) or graphene, as described further herein below. Electrode layer 30 grows on substrate—not shown in the FIG. 1. PIN junctions 20 are sandwiched between and in complete electrical contact with the upper and lower electrodes. In other embodiments of the current invention, either or both of electrodes 30 and 25 may be fabricated from a graphene electrodes or CTO or high sp² bonding (graphite) or any kind of conductive electrode, as known in the art. Notably, graphene electrodes apply to all kinds of devices and are not limited to multi-junction devices. Device 10 is exposed to a light source 35, such as, but not limited to sunlight. Upper electrode layer 25 is typically oriented closest to the light source and the upper electrode is fabricated with a high transparency to the incident light from the light source. Leads 40 are electrically connected to the electrodes and are connected to a load 45, such as, but not limited to a: electrical storage device, another electrical circuit, or another electrical/electronic device normally receiving power.

The PIN junction trios, comprising a:DLC layers have a number of important properties, as described herein below. All of the layers described herein have typical thicknesses as known in the art, approximately ranging from about 1 micron to about 0.1 micron, although thicknesses larger and smaller than this range are also possible.

The following table copied from [Aisenberg, S., Kimock, F. M., Mater. Sci. Forum, 52-53, (1988), 1], incorporated herein by reference, shows several key physical characteristics of the various classes of amorphous and crystalline carbon materials. Embodiments of the current invention include a:DLC layers having large band gaps (>4 eV), which serve to improve thermal conductivity and increased surface protection of a solar cell.

| | Key physical characteristics of several types of carbon | | | | |
|---|---|---|---|---|---|
| | materials [after Aisenberg et al.] | | | | |
| (a) Type of | Density | Optical gap | Hardness | sp³ | H |
| carbon | (g/m³) | (eV) | (Gpa) | (%) | (%) |
| Graphite | 2.27 | 0.0 | — | 0.0 | 0.0 |
| Glass carbon | 1.3-1.6 | 0.0 | 2-3 | ~0 | ~0 |
| Evaporation | 1.9-2.0 | 0.4-0.7 | 2-5 | <5 | <5 |
| Sputtered C | 2.2-2.6 | 0.6-0.9 | 10 | 5-10 | <5 |
| on Si (77K) | | | | | |
| i-C | 2.9-3.4 | 2.5 | 100 | >85 | <5 |
| Hard a:DLC | 1.6-2.0 | 1.2-1.6 | 10-30 | 40-50 | 30-50 |
| Soft a:DLC | 0.9-1.2 | 1.6-4.0 | <5 | 50-80 | 50-60 |
| Polyethylene | 0.9 | 6.0 | 0.01 | 100 | 66 |
| Diamond | 3.52 | 5.5 | 100 | 100 | 0.00 |

Typically, a:DLC layers 20 are selectively fabricated with the highest sp³/sp² ratio in layers closest to the light source and with the lowest sp³/sp² ratio furthest from the light source. In this manner, device 10 has an optimized response to the light source in that only longer wavelength light is absorbed and converted to electrical current in the PIN junction closest to the light source and so that shorter wavelength light passes through the layers closest to the light source and onward to subsequent layers, where the light is selectively absorbed and converted to electrical current. Selectively forming PIN junctions 20 having a:DLC layers with sp³/sp² ratios ranging from about 4.0 eV or more (layers associated with more diamond-like properties, including high transparencies) to about 0.5 eV (layers associated with more graphite-like properties) allows device 10 to have an optimized spectral response.

Furthermore, one process may be used in embodiments of the current invention to form PIN junctions 20 with a:DLC layers in a near-continuous fashion, based upon hard and soft a-C:H. Fabrication of device 10 may be done upon glass substrates, by growing conductive electrode layer 30 from solid graphite and then by fabricating all of the a:DLC layers above the electrode in one process. In this way, a:DLC layers may be the equivalent of one continuous film with varying properties, expressed by controlled and varying sp³/sp² ratios and by appropriate doping (to create n-doped, p-doped, and intrinsic layers, as known in the art) as described herein below, in the film, moving from the lower electrode to the upper electrode.

In embodiments of the current invention, Ag (silver) may be incorporated as a doping material in a:DLC layers 20, to reduce recombination and increase lifetime of carriers, thereby influencing a:DLC electronic properties. This phenomenon was reported in the following sources, incorporated herein by reference: H. Biederman, L. Martinu, D. Slavinska, I. Chudacek, Pure & Appl. Chem., 60 (1988), 607; H. Biederman, Z. Chmel, A. Fejfar, M. Misina, J. Pesicka, Vacuum, 40 (1990); P. Sheng, Y. Abeles, P. Arie, Phys. Review

Letters, 31 (1977), 44; and D. Babonneau, T. Cabioc'h, A. Naudon, J. C. Girard, M. F. Denanot, Surface Science, 409 (1998), 358. While there are several other doping materials for a:DLC, such as Na, I, and B, all of them produce p-type doping. Thus, an efficient idea is to dope a:DLC, which is a p-type, to obtain an n-type a:DLC required for making the device based on p-n junctions (e.g., diodes and transistors). Additional advantages of Ag doping include: improved doping uniformity, decreased resistivity (the current ratio R=(I_{L}-I_{d})/I_{L} (I_{d} current in dark) and under light(IL); additional effect of negative photoconductivity; and energy gap improvement/increase of solar cell current.

Another secondary advantage related to Ag doping of a:DLC is for surface-enhanced Raman spectroscopy—in offline process control. This is based on the fact that a small percentage of diamond content cannot be distinguished in the presence of graphite, because the scattering cross-section for graphite is 50 times greater than it is for diamond. However, if a very small amount of silver is sputtered onto the surface of an a:DLC film, the Raman lines characteristic of diamond are enhanced dramatically.

In embodiments of the present invention, an Ag-a:DLC film may be grown on a substrate (not shown in the figure) of silicon, glass, plastic, sapphire substrate, and any other suitable material by an RF sputtering method, where a mixture of Ar+CH₄ gas is introduced into a chamber with an Ag plate as one of the electrodes. Alternatively, the Ag source can be introduced in a different form, such as a gaseous form.

In the multi-junction structure shown in FIG. 1 the connections between each junction can be a conductive transparent layer, a tunneling diode or a directing diode. The top junction of this multi-junction has the widest band and each of the successive junctions having a descending band gap value. The connection between the top junction and the rest of the junctions therein below are achieved with separating insulating and transparent layers and by depositing a bottom electrode to the top junction and a top electrode to the bottom multi junctions stack. Then, taking out connecting wires from the top junction electrodes to connect with the current circuit of the bottom multi-junctions. A person of ordinary skill in the art would readily appreciate that all combinations of the following structures can be used for such multi-junctions, and include, but are not limited to, DLC as semiconductor, DLC as a window, combinations with Silicon or Silicon junctions, as well as other appropriate devices.

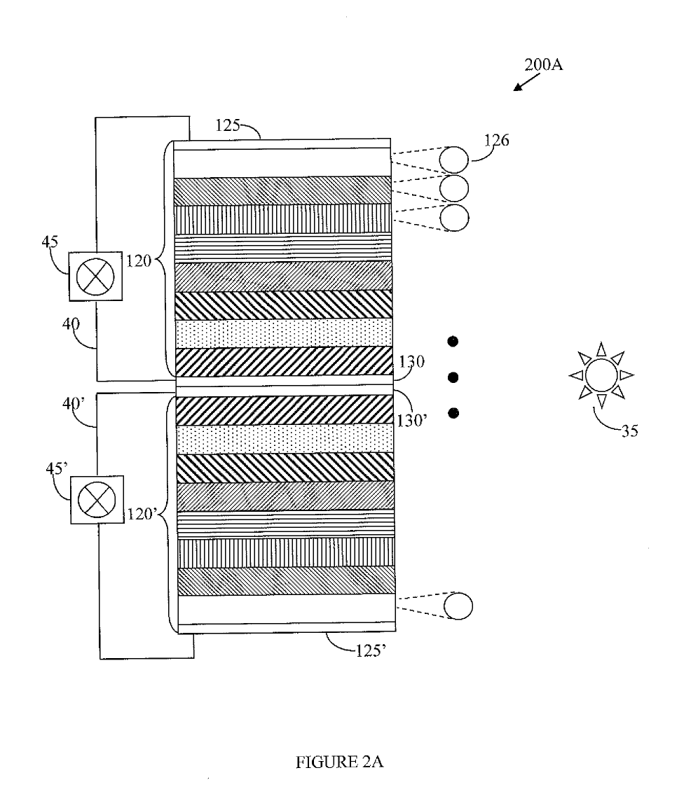

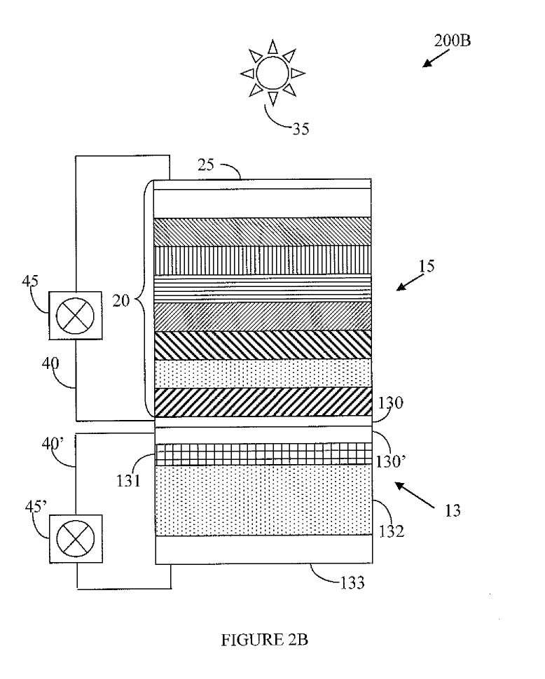

Reference is now made to FIG. 2A, which is a schematic diagram of an enhanced device 200A, such as a PV cell or solar cell, in accordance with an embodiment of the current invention. Apart from differences described below, enhanced device 200A is generally similar in operation to that of device 10 shown in FIG. 1, having a mirror image device from both sides of the substrate, so that elements indicated by the same reference numerals are generally identical in configuration and operation.

A plurality of films comprises a number of PIN junctions 120 and 120′ (similar to PIN junctions 20 as shown in FIG. 2A); upper electrode layers 125 and 125′ (similar to upper electrode layer 25 as shown in FIG. 2A.), and lower electrode layers 130 and 130′ (similar to lower electrode layer 30 as shown in FIG. 2A). In the current figure it can be seen that two devices 10 are configured with their respective lower electrodes in close proximity, although the electrodes are typically insulated from one another (not shown in the figure). One example of such insulation is a non-conducting substrate or, alternatively, it may be a grounding conducting material, serving as a common ground, upon which the enhanced device may be grown.

Leads 40 and 40′ and loads 45 and 45′ function generally similarly to leads 40 and load 45 shown in FIG. 2A. Additionally or alternatively, illumination incident on device 200A may be further absorbed by some or all of PIN junctions 120′ to further generate electricity. In embodiments of the current invention, a:DLC layers in PIN junctions 120 and 120′ are selectively fabricated in terms of sp³/sp² ratios, as previously noted, to optimize overall operating performance of device 100. FIG. 2A shown another embodiment of the current invention is a concentration optic system, using the micro optic components for focusing the light directly to the edge side of the every PIN junctions to decrease efficiency. Unlike the device 100, the light comes through the upper area and transfers through junction to next junction, in device 200A the light is focused straight on the side section profile of each junction.

In other embodiments of the current invention, devices 10 and 100 take advantage of a single micro-lense which concentrates the incident light spectrum into any of the PIN junction having different absorption bands. This design can be extended to a number of semiconductor converters. Fresnel lenses 126 may be used to collect incident light and direct it into a pyramidal concentrator. The concentrator delivers the light to small dichroic optics, in this case a prism, which divide the input light between solar cells that absorb different spectral bands. FIG. 2A

An additional advantage of using a:DLC with high sp³/sp² ratios for selective layers is that a:DLC having these high ratio values is highly thermally conductive. These properties may be used advantageously to thermally manage devices 10, 100 and to enhance their performance in general. Also, the use of thin layers generally aids in overall thermal management of the devices.

The a:DLC material of the present invention can be further coupled to, or associated with a number of different components in order to create various devices. Referring now to FIG. 2B, shows an embodiment 200B device that is a combination of device 10 or 100 on one side of the substrate and on the other side an a:DLC thermoelectric conversion device 13 configured as an electricity generator. Notably, the cathode 131 has a layer of diamond-like carbon material coated on the back side of substrate 130′. An intermediate a:DLC member 132 is electrically coupled to the electron emission surface 133 of the diamond-like carbon material too. A DLC with high sp² bonding anode 133 can be electrically coupled to the intermediate member opposite the diamond-like carbon material. The energy collector from 35 in multi-junction 15 can be included as desired, in order to enhance the collection and transmission of thermal and photonic energy to both a:DLC devices. For example, when light from illumination source 35 is incident on upper electrode 125 and is selectively absorbed in PIN junctions 120, heat is generated, as the device functions as a thermionic device. Generated heat is conducted through PIN junctions 120 and through lower electrodes 130 and 130′ to PIN junctions 120′, where a portion of the thermal energy generated is converted to electrical energy, recovered by leads 45′. The other advantage of this principle is that incident light is concentrated upon every PIN junction, similarly to the device 200A in FIG. 2A, and combined with a thermal management device 13 shown in FIG. 2B, that is used to increase overall efficiency. The advantage of enhanced device 10 or 100 is that the exemplary configuration shown has a:DLC layers optimized in terms of spectral response to light source 35 and in terms of overall thermal management of the device.

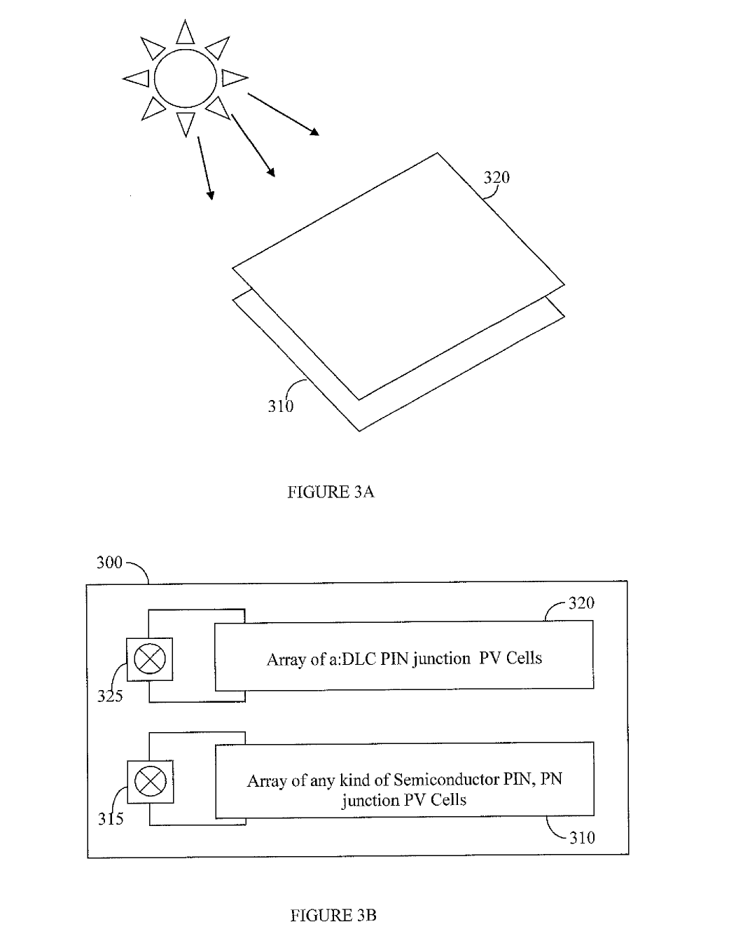

In yet another embodiment the performance of standard semiconductor PIN junction of photovoltaic cells having a first band gap, formed in a first structure, are augmented with a second structure formed of one (not shown) or more (shown for example element 15 in FIG. 1) layers of a:DLC PIN junction, such that the one or more band gaps of the second structure are different than that of the first structure. The advantage of this structure is in the ability to increase the efficiency of the area used to convert solar energy into electrical energy over the one which is typical for standard semiconductor based PV cells. Furthermore, this allows the upgrade of currently installed solar systems that are based on semiconductor PV cell arrays by providing an additional layer of the a:DLC based array that has one or more band gaps that are different from that of the semiconductor PV cells, and as shown in the exemplary and non-limiting FIG. 3A, comprising of the first structure 310 and the second structure 320. The solution, shown in FIG. 3B comprises therefore from a structure 310 which is basically a standard. semiconductor PIN junction array 310 and a second structure 320 comprised of an a:DLC junction array 320. Each array is coupled respectively to loads 315 and 325, essentially in the same manner discussed earlier herein, where a load may be but is not limited to: electrical storage device, another electrical circuit, or another electrical/electronic device normally receiving power. A person of ordinary skill in the art would readily appreciate, that while this invention discusses herein essentially separate first structure 310 and second structure 320, a fully integrated apparatus where the second structure 320 is manufactured on top of the structure 310 with appropriate electrical connections and/or isolations. The PIN junctions may be formed of materials such as, but not limited to, crystalline silicon, amorphous silicon, germanium, gallium-arsenide, copper indium gallium selenide (CIGS), organic semiconductor for PV cell, dye cell semiconductor and the likes.

Accordingly it should be understood that the top two junctions can be created in a continuous process or mechanically integrated to each other according to their band gap, and as explained hereinabove. In a continuous process mode the connection between the junctions should be done using a conductive electric connection layer, a conductive transparent layer, a tunneling diode, or a direction diode. These junctions can be integrated in serial mode. When parallel mode connection is used, each junction is separated from another junction by an insulating and transparent layer and each junction has a top electrode and a bottom electrode connected for each individual junction. Hence, each of the diodes can provide current independently of the other diodes and therefore not be limited in current providing to the lowest common denominator, i.e., the diode that provides the least amount of current in a series connection.

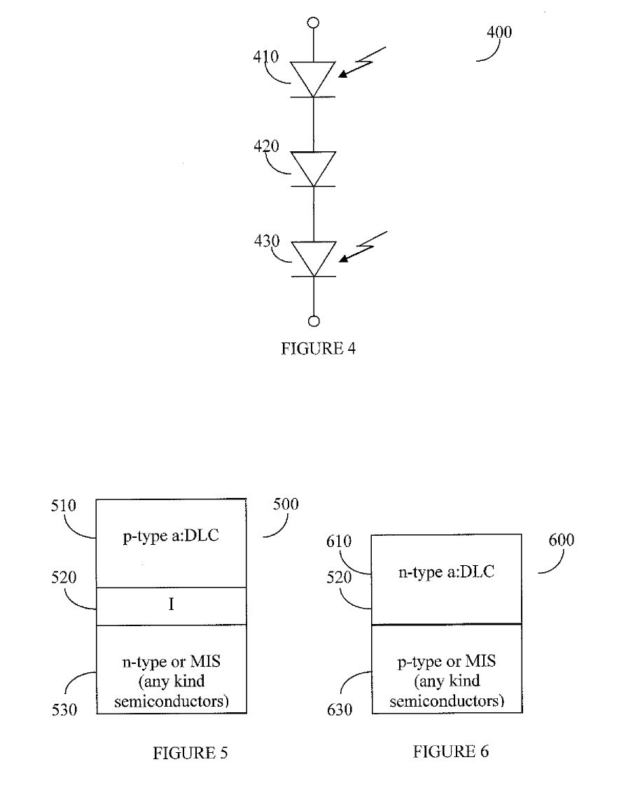

FIG. 4 is an exemplary and non-limiting electrical schematic 400 of the connection of a silicon or any kind of PV PIN junction 410 to an a:DLC PIN junction 430 by a current directing tunnel diode 420 according to a principle of the invention. When connecting a plurality of PIN junction such as 410 and 430 it is advantageous to connect a directing tunnel diode 420 to establish the current flow through the structure described in the circuit 400. This ensures current flow in a predetermined direction. Between any kind of PV PIN junction 410 and an a:DLC PIN junction 430 there is built a directing tunnel diode 420. The structure formed of 410, 420, and 430 can be stacked alone or introduce into any stack of a multi-junction DLC stack. It should be understood by a person of ordinary skill in the art that a PIN junction may be, but not by means of limitation, formed by using an a:DLC layer over silicon and other semiconductor materials may be used without departing from the scope of the invention.

The two junctions 410 and 430 shown in FIG. 4 can be created in a continuous process or integrated mechanically in a descending band gap and as further explained hereinabove. The connection between junctions 410 and 430 with junction 420, can be done in a continuous process by a conductive transparent layer, a tunneling diode, or a direction diode. These junctions can be integrated in a serial mode. When a parallel mode connection is used each junction is separated from the other junction by an insulating and transparent layer that replaces the junction 420, and with further circuit connections between the electrodes so that each junction providing current can be accessed separately. Each of the junctions 410 or 430 can be the top or bottom junction based on the desired design, each one becoming and independent junction.

FIG. 5 depicts and exemplary and non-limiting schematic diagram of the layers comprising a PIN junction according to a principle of the invention. Each PIN junction, for example PIN junction 410 and 430 comprises three layers. A first layer 510 comprises the p-type semiconductor and fabricated as an a:DLC layer having a predetermined sp³/sp² ratio as discussed hereinabove. A third layer 530 which is the n-type of the PIN junction or metal-insulator semiconductor (MIS). Between the layers 510 and 530 there is a second layer 520 which is an intrinsic layer preferably from an a:DLC material. A person of ordinary skill in the art would now readily appreciate that it is also possible to create the same stack where the n-type semiconductor is fabricated as an a:DLC layer and the p-type semiconductor as an n-type silicon material or any kind of PV semiconductor or opposite.

As noted above, a plurality of PIN junction may be connected in series, preferably with a current directing tunnel diode as described with respect of FIG. 4 above, each PIN junction have its predetermined sp³/sp² ratio to maximize the solar energy conversion into electrical energy. In the more general case a diode 600 can be manufactured in accordance with the principles of the invention as shown in FIG. 6. A p-type is fabricated as an a:DLC semiconductor layer 610 over an material that is an n-type material or metal-insulator semiconductor (MIS) 630, regardless of which kind of semiconductor is used, crystalline silicon, amorphous silicon, germanium, gallium-arsenide, copper indium gallium selenide (CIGS), organic semiconductor for PV cell, dye cell semiconductor and the likes, and any kinds of crystalline and amorphous PV cell materials. The reverse is also true, where the p-type material is any kind of semiconductor and the N material is an a:DLC or all kinds of combination between them to integrated multi junction PV. A person of ordinary skill in the art would readily appreciate that each n-type or p-type layers can be above or below the device according to the design requirements and without departing from the scope of the invention. In addition the top semiconductor layer can be used as a passive transparent window for the active semiconductors layers (n or p) therein below.

One deposition process for a:DLC films was using a RF (13.56 MHz) glow discharge with a hydrocarbon (CH.sub.4) or a hydrocarbon mixture with other gases or doping gas. Combination of DLC deposition with other materials requires coordination and integration of processes between multiple systems. In one experiment, deposition was made after evacuating the chamber to a pressure of 1.33×10⁻⁴ Pa. The dimensions of the vacuum chamber were: 50 cm. diameter and 80 cm. in height. The diameter of the electrode was 20 cm with a spacing of 8-10 cm between anode and cathode. The electrode also served as a substrate holder and was water-cooled. The power electrode (so-called cathode) was RF self-biased negatively at a voltage V_{b} relative to ground. Thus, it was subjected to ion bombardment (for example, by C⁺).

The CH₄ pressure admitted between few of tens of milli torr and a discharge power varied from 50 to 400 W (self-bias from −100 to −1000V). The purity of the admitted gases in the chamber was more than 99.99% to obtain a:DLC films with high purity and good adhesion, After particles were filtered, mass flow control (MFC) was used to control gas entry into chamber._These conditions, used for laboratory feasibility testing, should not necessarily be the basis for mass production process, and therefore should not be viewed as limiting the scope of the invention. In an industrial manufacturing process, these dimensions may not be relevant in whole or in part. Accordingly, the innovation disclosed herein teaches the building of a multi junction device, requires a continuous process where “one process” means that the process is roll-to-roll as commonly used with respect of thin films in the industry, where process conditions are not limited to sub-atmospheric pressures.

Composite films grown on electrically grounded or floating substrates are subjected to electron and ion bombardment. Under usual discharge conditions, the floating or grounded substrate is negative against a plasma potential (about 10V drop). Positive ion bombardment with this average energy is of special importance as it enhances the plasma polymerization via production of surface free radicals. In the case of an ordinary planar magnetron, the potential drop is lower and most of the electrons are trapped by the tunnel magnetic field. The situation changes if an increased U_{B} acts on the substrate via capacitive coupling of an independent RF generator or by splitting the original RF power. A simple solution is to place the substrate on the excitation electrode, for instance, an Ag plate, or other appropriate metals, in deposition plasma when CH₄+Ar gases are used, competitive reactive Ar ions etch the substrate, removing Ag atoms and simultaneously with the decomposition of CH₄, a:DLC-doped with Ag films are generated. Increasing Ar partial pressure in the process increases the Ag concentration in films.

For deposition of Ag in a:DLC films a vacuum chamber is used where the Ag foil is placed as one of the electrodes and substrates as a second electrode. The ratio of flow rate of gases is controlled by mass flow control (MFC). The ranges of Ar partial pressure [%,] relative to the total pressure of CH₄+Ar (6.7×10⁻¹ Pa), are measured using a Micro Pole Analyzer in the chamber. The Ag doping level is known and gas source precursors or evaporated liquid gas is used.

According to typical roll-to-roll processes, Ag or other metal doping source maybe replace with Metalorganic vapour phase or gas source compound for a continuous process. In one embodiment of a process for multi-junction devices it may be possible to grow graphene layers based on the same hydrocarbon. gas used to grow a:DLC layers as part of the platform for coating conductive and transparent electrode substrates.-In one embodiment of the invention a combination of DLC junction, having anti-reflective properties, together with other existing process cells PV materials, such as Silicon, an assembly line to replace conventional anti-reflective layer reduces cost and increases the efficiency.

Embodiments of the current invention, using a:DLC as described hereinabove, may further be applied to conventional and microelectronic integrated circuit fabrication, with or without application of the PIN junctions noted hereinabove. Such applications include, but are not limited to: variable electronic dimmers, detectors and variable light sensors (large spectrum of wavelength in one detector), transistors, capacitors (nano capacitors with variable capacity), variable antifuse, field emission devices, variable resistance assemblies, and an array of protective optics windows having variable electronic, mechanical, and optics qualities, silicon and other photo Volta cell improvements, variable low dielectric constant films for ULSI, protective coating areas with different electronic, mechanic, optic, and morphology properties for magnetic storage disks, optical windows, micro-electromechanical devices (MEMs), solid state relays, thermostats for any kind of electronic devices, waveguide sensing systems, medical devices, micro-optical component coating, and MEMS product systems.

It will be appreciated that the above descriptions are intended only to serve as examples, and that many other embodiments are possible within the scope of the present invention as defined in the appended claims.

1. An apparatus for conversion of solar energy into electrical energy comprising:
a first electrode;
a PIN junction photo diode formed over the first electrode;
at least an a:DLC PIN junction formed over the tunnel diode serially connected to the tunnel diode; and
a second electrode formed over the at least an a:DLC PIN junction;
wherein the band gap of the at least an a:DLC PIN junction is different from the band gap of the PIN junction.

2. The apparatus of claim 1, further comprising:
a tunnel diode for directing current through the apparatus, the tunnel diode formed over the PIN junction for serial connection with the silicon PIN junction.

3. The apparatus of claim 1, wherein the PIN junction is made of one of:
crystalline silicon, amorphous silicon, germanium, gallium-arsenide, copper indium gallium selenide (GIGS), dye solar, organic semiconductor.

4. The apparatus of claim 1, wherein the at least an a:DLC PIN junction is comprised of a first a:DLC PIN junction and a second a:DLC PIN diode connected in series.

5. The apparatus of claim 4, wherein the first a:DLC PIN junction and the second a:DLC PIN junction each have different band gaps which are different from the ban gap of the silicon PIN junction.

6. The apparatus of claim 5, wherein a band gap of an a:DLC PIN junction closer to the first electrode has a wider band gap than a subsequent a:DLC PIN junction closer to the second electrode.

7. The apparatus of claim 1, further comprising:
at least a Fresnel lens that collects incident light.

8. The apparatus of claim 1, further comprising:
a structure to collect thermal energy for conversion to electrical energy.

9. An array of cells for conversion of solar energy into electrical energy,
wherein each cell of the array of cells is the apparatus of claim I.

10. A method of manufacture of a structure for conversion of solar energy into electrical energy, the method comprising:
forming a first electrode of conductive material;
forming a PIN junction photo diode over the first electrode having a first band gap;
forming at least an a:DLC PIN junction over the tunnel diode that is serially connected to the tunnel diode, wherein each of the at least an a:DLC PIN junction having a predetermined band gap; and
forming a second electrode formed over the at least an a:DLC PIN junction;
wherein the band gap of the PIN junction and each of the predetermined band gap are different from each other.

11. The method of claim 10, further comprising:
forming a current directing tunnel diode over the PIN junction such that a serial connection is created between the PIN junction and the tunnel diode.

12. The method of claim 10, wherein the PIN junction is made of one of:
crystalline silicon, amorphous silicon, germanium, gallium-arsenide, copper indium gallium selenide (CIGS), dye solar, organic semiconductor.

13. The method of claim 10, further comprising:
forming at least a Fresnel lens for collection of incident light.

14. The method of claim 10, further comprising:
forming a structure that collects thermal energy for conversion to electrical energy.

15. A method of manufacture of an array of structures for conversion of solar energy into electrical energy, the method comprising:
forming a first electrode of conductive material;
forming a plurality of PIN junction photo diode over the first electrode having a first band gap;
forming a plurality of at least an a:DLC PIN junction over the respective plurality of tunnel diodes each of the at least an a:DLC PIN junction being serially connected to s respective tunnel diode, wherein each of the at least an a:DLC PIN junction having a predetermined band gap; and
forming a second electrode formed over the plurality of at least an a:DLC PIN junction;
wherein the band gap of the plurality of PIN junctions and each of the predetermined band gap are different from each other.

16. The method of claim 15, further comprising:
forming a plurality of tunnel diodes over the respective plurality of PIN junction such that a serial connection is created between respective PIN junction and tunnel diodes.

17. The method of claim 15, wherein the PIN junction is made of one of:
crystalline silicon, amorphous silicon, germanium, gallium-arsenide, copper indium gallium selenide (CIGS), dye solar, organic semiconductor.

18. The method of claim 15, further comprising:
forming at least a Fresnel lens for collection of incident light.

19. The method of claim 15, further comprising:
forming a structure that collects thermal energy for conversion to electrical energy.

20. A diode comprising:
a first layer made of semiconductor layer having a first polarity; and
a second layer made of an a:DLC layer having a second polarity, the second polarity being opposite to the first polarity;
such that a PN junction is formed between the first layer and the second layer.

21. The diode of claim 20, wherein the first polarity is one of: p-type, n-type.

22. The diode of claim 20, further comprising:
an intrinsic layer between the first layer and the second layer.

23. The diode of claim 22, wherein the intrinsic layer is from an a:DLC material.

24. The diode of claim 20, wherein the semiconductor is one of: crystalline silicon, amorphous silicon, germanium, gallium-arsenide, copper indium gallium selenide (CIGS), dye solar, organic semiconductor.

25. An apparatus for conversion of solar energy into electrical energy comprising:
at least an a:DLC PIN junction having a first band gap; and
at least another device for conversion of solar energy into electrical energy having a second band gap that is different from the first band gap;
wherein each of the at least an a:DLC PIN junction and the at least another device providing current from the apparatus in one of: parallel to each other; in series of each other.

26. The apparatus of claim 25, wherein the at least another device is one of: a crystalline silicon PIN junction photo diode, an amorphous silicon PIN junction photo diode, a gallium-arsenide PIN junction photo diode, a crystalline PIN junction photo diode, a copper indium gallium selenide (CIGS) PIN junction photo diode, a dye solar PIN junction photo diode, an organic semiconductor PIN junction photo diode, an a:DLC PIN junction.

27. The apparatus of claim 25, further comprising:
at least a Fresnel lens that collects incident light.

28. The apparatus of claim 25, further comprising:
a structure to collect thermal energy for conversion to electrical energy.
